(19) United States
(12) Patent Application Publication
(10) Pub. No.: US 2016/0372558 A1
(43) Pub. Date: Dec. 22, 2016

(54) High Voltage Vertical FPMOS Fets

(71) Applicant: SANKEN ELECTRIC CO., LTD., Niiza-Shi (JP)

(72) Inventor: Shunsuke FUKUNAGA, Saitama-shi (JP)

(21) Appl. No.: 14/743,333

(22) Filed: Jun. 18, 2015

(51) Int. Cl. H01L 29/417; H01L 29/423; H01L 29/10; H01L 29/739; H01L 29/06; H01L 29/08; H01L 29/40; H01L 29/78

(52) U.S. Cl. CPC H01L 29/41766; H01L 29/402; H01L 29/41741; H01L 29/4236; H01L 29/7813; H01L 29/7397; H01L 29/0696; H01L 29/086; H01L 29/1079

(57) ABSTRACT

Semiconductor power devices such as vertical FPMOS are described having a plurality of trenches formed at a top portion of a semiconductor substrate extending laterally across the semiconductor substrate along a longitudinal direction. Each trench has sidewalls generally perpendicular to a longitudinal direction of the trench and extending downward from a top surface to a trench bottom. Gate electrodes and source electrodes are positioned in the trenches. Higher voltage resistance is achieved while increasing current by spacing the trenches and providing particular dopant levels to allow more even distribution of depletion layer regions across a power device during use.

### FIELD OF THE INVENTION

The disclosure relates generally to semiconductor power device structures. Particular embodiments relate to vertical FPMOS (Field plate metal-oxide-semiconductor) structures that can withstand higher voltage without requiring peripheral trench structure.

### BACKGROUND

Conventional technologies for reducing power semiconductor device gate to drain capacitance while increasing voltage resistance and current are still plagued with technical limitations. Because of growing demands for high frequency switch power devices, an urgent need exists to resolve these technical difficulties and limitations. For power transistors including MOSFET and IGBT (insulated-gate bipolar transistor), a new device configuration and manufacturing process are necessary to reduce the speed-limiting capacitance between the gate and the drain of these switching power devices.

Gate to drain capacitance, Cgd. degrades switching performance of MOSFETs. Various techniques have been proposed for reducing Cgd. One proposal, described in U.S. Pat. No. 7,557,409 uses a super trench MOSFET, wherein a source electrode is buried in the lower portion of the trench to reduce the gate-to-drain capacitance, improving the ability of the MOSFET to operate at high frequencies. The trench buried source electrode is insulated from the epitaxial layer and semiconductor substrate but is in electrical contact with the source region. The substrate advantageously includes a plurality of annular trenches separated by annular mesas and a gate metal layer that extends outward from a central region in a plurality of gate metal legs.

Another proposal has been to increase the thickness of the gate oxide layer at the bottom of the trench, as suggested in U.S. Pat. No. 4,914,058 to Blanchard. In Blanchard, the MOSFET as an N-channel device is formed in an epitaxial (epi) layer that is grown on an N+ substrate. A trench extends through the epi layer and into N+ substrate. The epi layer is generally doped with an N-type impurity such as phosphorus. The epi layer also includes an N+ source region and a P body, both of which are contacted by a metal layer. The background N-type doping of the epi layer is found in an N-drift region. The N+ substrate and the N-drift region represent the drain of the Blanchard MOSFET.

The sidewalls of the trench are lined with a gate oxide layer, and trench is filled with a gate electrode, which is typically made of polycrystalline silicon. (polysilicon) that is doped heavily to make it conductive. A thin gate oxide was grown on the walls and floor of trench. Noteworthy is that the Blanchard MOSFET has sidewalls that are lined but not independent structures such as gates. At the bottom of the trench is a thick oxide layer that serves to reduce the capacitance between the polysilicon gate and the drain (the N+ substrate and the N-drift region).

Baliga discloses in U.S. Pat. No. 5,998,833, and in particular FIG. 3, a DMOS (double-diffused metal-oxide-semiconductor) cell as an example of conventional art. Baliga's disclosure shows use of a source electrode 128a underneath the trenched gate 127 to reduce the gate-to-drain capacitance. Both source electrode 128a and trenched gate 127 are in the trench defined by side walls 120a. The gate of the DMOS cell is divided into two segments. The gate-to-drain capacitance is reduced because contributions to capacitance from the gate-drain overlapping areas are eliminated.

Another example of conventional art is shown as FIG. 1 in U.S. Pat. No. 6,690,062. This reference teaches an improvement in the switching behavior of a trenched MOS power transistor by providing a shielding electrode 17 in an edge region 4. The shielding electrode surrounds at least sections of an active cell array 2. Gate electrodes 10 are configured in trenches 9. There is a capacitance between an edge metallization gate structure 20 and a drain zone 16. The shielding electrode 17 located in the edge region 4 reduces the capacitance between an edge gate structure and a drain zone 16 and hence reduces the gate-drain capacitance of the transistor.

The above described transistor configurations still have a common difficulty. The source electrode disposed on the trench bottom is connected to the source voltage through an edge area of the semiconductor power device. This inevitably increases the source electrode resistance. Furthermore, the extra masks needed to create such connection also increase the cost of manufacturing.

Therefore, a need still exists in the art of power semiconductor device design and manufacture to provide a new manufacturing method and device configuration in forming the power devices such that the above discussed problems and limitations can be resolved.

An electronic device includes a drift region having a first conductivity type and a grid including a plurality of doped regions formed in the drift region and having a second conductivity type. The doped regions have a dopant concentration greater than 2.2.times.10.sup.19 cm.sup.-3

A vertical SiC-MOSFET formed in this way is expected to be utilized as a switching device having low ON-resistance and switchable at high speed in power conversion equipment such as an inverter for motor control and an uninterruptible power supply (UPS). However, when high voltage is applied between a source and a drain, the high voltage is applied not only to an active region through which current flows during on-time but also to an edge termination structure region that is disposed in a peripheral portion of the active region and that sustains the breakdown voltage. When high voltage is applied, the edge termination structure region has a depletion layer spreading in a lateral direction (a direction parallel to a substrate principal plane) and is, therefore, susceptible to electrical charge of the substrate surface. As a result, breakdown characteristics become unstable.

Another complicated proposed solution presented by Nobuyuki et al. in JP2013-069852A “Semiconductor Device” is to build the source electrode deep in the trench, but add extra insulation lining the trench near the trench top, between the source and the base. See FIG. 1. This figure shows parallel-arranged trenches 10 with centrally positioned source electrodes 20 with gates 30 arranged near the channel tops between source 20 and base P regions (shown as “P+”). A higher breakdown voltage is achieved by making the hatched insulation layer thicker in region 50. This disclosure continues the general teaching in this field to add structures, such as thicker insulation regions, to the trenches and in their peripheries. However, such added complexity is undesirable and generally increases space usage, and conflicts with the need for increased current capacity. In particular, peripheral trenches taught as a solution undesirably add cost and require space.

Trench technology has not heretofore been utilized to its fullest extent. Accordingly, this field needs a simpler way to enhance high voltage performance without increasing complexity or other trade-offs such as chip current density.

### SUMMARY

Embodiments provide a semiconductor power device disposed in a semiconductor substrate, comprising trenches having defined widths formed at defined intervals perpendicular to and across a top portion of the semiconductor substrate extending laterally across the substrate and extending into an epitaxial layer; base regions located outside the trenches; trench source electrodes inside the trenches; and gate electrodes inside the trenches positioned between the trench source electrodes and the base regions, wherein the intervals between trenches vs trench widths are at a ratio of 1.0 to 2.5 respectively. In an embodiment, the semiconductor power device has a base dopant concentration between 5×10E16 to 5×10E17 per cubic centimeter. In an embodiment the epitaxial layer has a dopant concentration of between 1.2E16 to 1.8E16 N− per cubic centimeter. In an embodiment the epitaxial layer has a dopant concentration of between 1.2E16 to 1.8E16 N− per cubic centimeter. In an embodiment the device lacks a peripheral trench structure.

In a preferred embodiment the trench source electrodes are centered in the trenches, and extend at least mostly to the bottom of the trenches. In another preferred embodiment the gate electrodes are between the trench source electrodes and the trench walls, and extend only partially into the trenches adjacent the base regions. In an embodiment the base regions are at the top of the epitaxial layer and extend down as far as the gate electrodes. In an embodiment the trench widths are approximately 1.5 microns. The term “approximately” as used here means within +/−25% of the value. In another embodiment the trench widths are between 1.35 and 1.65 microns. In a desirable embodiment the spacing between trenches is approximately 1.7 microns. The term “approximately” as used here means within +/−25% of the value. In a desirable embodiment the spacing between trenches is between 1.5 and 1.9 microns. In an embodiment the power device develops depletion regions along the trenches that expand uniformly with applied voltage. In an embodiment uniform depletion regions develop with application of applied voltage between 50 and 150 volts.

Another embodiment provides a vertical FPMOS having high voltage resistance without peripheral trench structure, comprising a semiconductor substrate with an epitaxial layer, parallel trenches of defined widths at defined intervals across a top portion of the semiconductor substrate extending laterally across the substrate and extending into the epitaxial layer wherein the defined intervals between trenches vs defined trench widths are at a ratio of 1.0 to 2.5 respectively; base regions located outside and near the tops of the trenches; source electrodes inside the trenches; and gate electrodes inside the trenches positioned between the source electrodes and the base regions, wherein the location and doping of base and epitaxial regions are arranged to provide uniform expansion of the depletion layer, thereby providing high voltage resistance. In an embodiment the vertical FPMOS has a base dopant concentration between 5×10E16 to 5×10E17 per cubic centimeter. In an embodiment the N-epitaxial layer has a dopant concentration of between 1.2E16 to 1.8E16 per cubic centimeter. In an embodiment the N-epitaxial layer has a dopant concentration of between 1.2E16 to 1.8E16 per cubic centimeter.

In a desirable embodiment the vertical FPMOS lacks a peripheral trench structure. In an embodiment the source electrodes are centered in the trenches, and extend at least mostly to the bottom of the trenches. In an embodiment the gate electrodes are between the source electrodes and the trench walls, and extend only partially into the trenches adjacent the base regions. In an embodiment the trench widths are approximately 1.5 microns. In an embodiment the trench widths are between 1.3 and 1.7 microns. In an embodiment the spacing between trenches is approximately 1.7 microns. In an embodiment the spacing between trenches is between 1.5 and 1.9 microns. Other embodiments are intended as will be apparent to a skilled reader of this specification and of further details in the cited art therein which is already of record in the patent office.

### DESCRIPTION OF THE DRAWINGS

FIG. 1 shows trenched MOSFET structure.

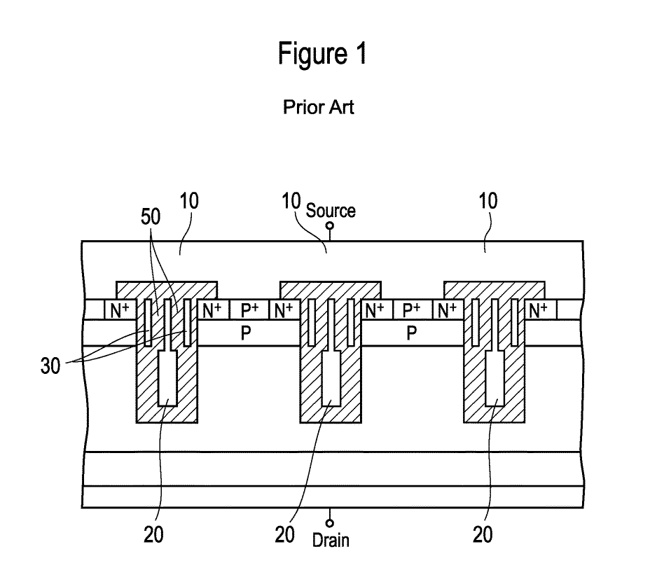

FIG. 2 is an embodiment of a trenched MOSFET.

FIG. 3 shows a depletion region versus voltage according to an embodiment.

FIG. 4 shows a depletion region versus voltage according to a conventional structure.

FIG. 5 shows a typical peripheral trench structure in conventional art.

FIG. 6 shows a top down view of an embodiment.

FIG. 7 shows an end view of an embodiment.

### DETAILED DESCRIPTION

Desirable embodiments achieve improved high voltage resistance with high current capability by a combination of trench width, spacing between trenches and careful selection of dopant levels. This surprisingly provided a structure that does not require further peripheral trench structures or more complicated dopant regions as otherwise championed by others in this art.

Without wishing to be bound by any one theory for how embodiments of the invention operate, it is believed that the discovery involves a structure that provides a more even depletion layer extending from the base during operation. The simultaneous depletion layers grow out more evenly, allowing more optimum packing of the trenches. This alleviates adding further peripheral trench structures and provides a more lower cost of manufacturing.

Desirably, MOS trenches are placed in such a way so as to couple the depletion region widths of the trenches, to one another evenly. This forms a structure that is able to withstand voltages up to the maximum value supported by the underlying epitaxial layer.

The generation of the depletion layer is a characteristic of all MOS structures. Here the nature of each depletion region, and thus the means of coupling of depletion region widths together, depends on both the applied voltage across the MOS system and the semiconductor dopant concentration. The spacing between the trenches is a key factor in depletion region width coupling. Accordingly, the spacing of trenches and the width of the trenches are significant dimensions that led to the reduced capacitance, higher switching speed and other benefits.

### Basic Structure

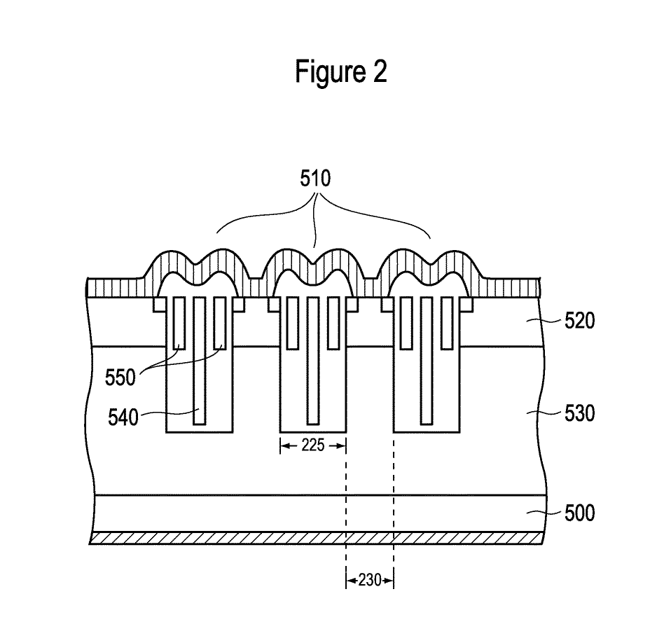

FIG. 2 shows a trenched MOSFET according to an embodiment. With reference to FIG. 2, the trenches are formed in the body (base) layer and the epitaxial layer of the substrate. In an embodiment, the trench is lined with a dielectric or an insulator. In an embodiment the trench is lined with silicon dioxide.

A hatched layer drain electrode is shown on the bottom surface of the substrate. Above the drain electrode is the unhatched N+ layer (also called the N+ substrate), above which is the N− layer (N epitaxial layer or epi layer) and above that is the P− layer, which is the body or base region. N+ region, a source region, is formed within the base region.

FIG. 2 shows three trenches 510 formed through base region 520 and into N− layer 530. Each trench has a trench source electrode 540, also known as a sealed electrode. On each side of trench source electrode 540 is a gate electrode 550. In an embodiment, the length Lg of both gates in each trench is approximately the length of the base region 520. In an embodiment Lg is at least 10 percent longer than base region 520. In an embodiment Lg is at least 25 percent longer than base region 520. In an embodiment Lg is up to 10 percent shorter than base region 520. In an embodiment Lg is 10 to 25 percent shorter than base region 520. In an embodiment the length Ls of trench source electrode 540 is longer by extending approximately half way through the length Ln− of N− layer 530. In an embodiment Ls of electrode 540 is longer by approximately one quarter way through the length Ln of N layer 530.

The term “approximately” used above means plus or minus 25% of the stated value. For example, approximately half way means between 0.375 and 0.625 of the way.

Source electrode is formed at the top surface of the substrate, with pockets of silicon oxide placed on the top area across the width Wt of each trench. Thus the source electrode extends over the entire top surface of the substrate with the three trenches, and makes contact with the silicon oxide on top of each trench and makes contact with the top surface of the substrate elsewhere.

In an embodiment N+ source regions are formed within a top layer of the P− base region 520 as shown. The source electrode serves as a metal source pad and provides an external connection to the source regions and of trench source electrode 540. The source pad is insulated from gate electrode 550 and the source electrode by silicon oxide. When a positive voltage is applied to gate electrodes, the MOSFET device turns ON and a conducting channel is formed vertically along the walls of trenches 510 within the base region 520 between the source and the N− layer 530, also called the drift/epitaxial region.

A MOSFET is made up of many cells, and the more cells that are placed in parallel the lower the Rds (drain-to-source resistance in the ON state). This fact establishes the relationship between the ON resistance and the MOSFET's area, or die size as it is commonly called. The current-conduction-paths in the MOS device described are vertical paths, through the epitaxial layer and the substrate. The current channels are aligned generally parallel to the trenches. The vertical current paths in the trench design are inherently more efficient at packing more cells together in a small space such as a fixed die size than planar structures. The current flows associated with each trench are combined and outputted at the drain electrode.

### The Depletion Region

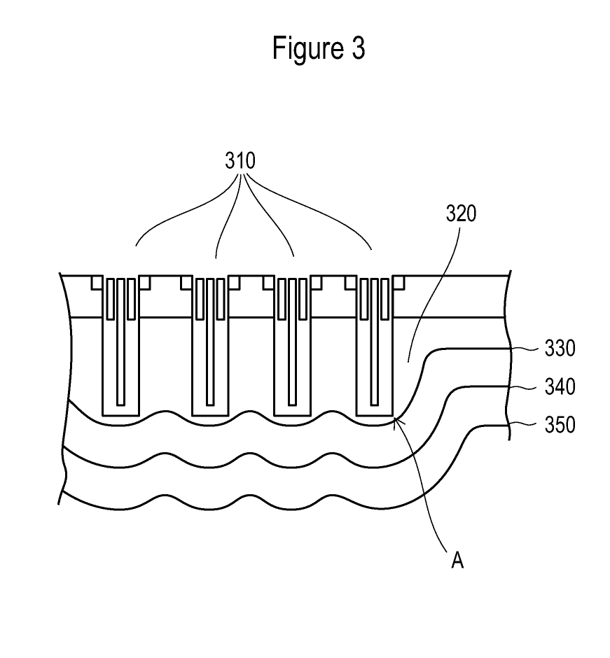

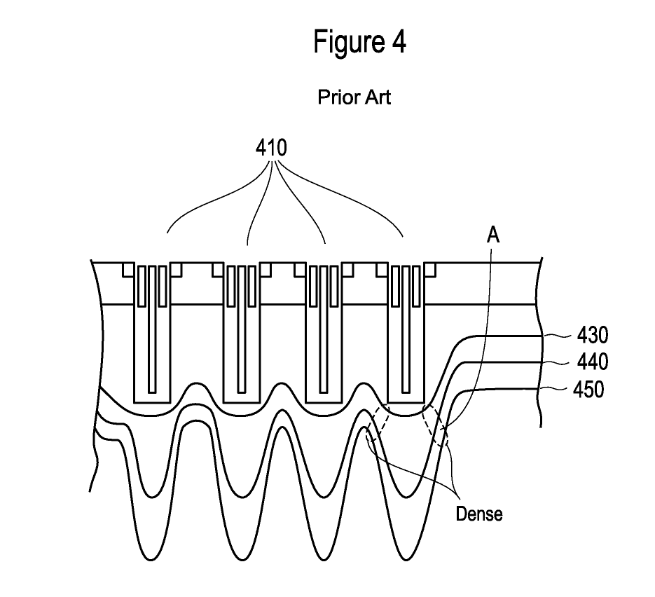

With reference to FIGS. 3 and 4, depletion layers are illustrated that exist in the region under the trenches. Four trenches are used for illustration purposes in FIG. 3. Each trench contributes a depletion region within each space of epitaxy substrate material between adjacent gate trenches, thus creating an expanding depletion region. With this expanded depletion region, the gate bus can support an increased operating voltage.

The expansion of the depletion areas away from the bottom of the trenches is illustrated for three Vcc voltages, 50, 100 and 150 VDC, shown as wavy lines in this drawing. It is seen that the depletion areas expand outwardly more with the higher Vcc voltages. As a result of the unique trenched MOSFET structure of the invention, the depletion areas generally expand uniformly, as is desired but not heretofore realized. This is in contrast to the conventional trenched MOSFET structure that exhibits a non-uniform expansion as seen in FIG. 4 where the wavy lines bunch up into a “Dense” region shown in FIG. 4. The expansion for any one of the three voltage depletion regions illustrated forms dense pockets at the bottom edges of each trench and this degradingly causes a low breakdown voltage for the MOSFET.

Although not shown as clearly in the figures, embodiments differ from art, such as the referenced art via a ratio of defined intervals between trenches to defined trench widths of 1.0 to 2.5 respectfully. In other words, the average interval (distance between) adjacent trenches divided by the average trench width is 1.0 to 2.5. In an embodiment, this ratio is approximately 1.0 to 2.5 respectfully, which means between 0.75 and 3.125 respectfully. Desirably, this ratio is maintained over a number of trench rows of at least 5, 10, 25 or more and in the absence of peripheral trenches. In an embodiment, the trenches are longer and closer than that in previous art due to lack of peripheral trenches. In a less desirable embodiment the ratio is 0.4 to 1.0.

For example, when 10 volts is applied to produce a depletion layer of x distance down into the layer, then when 20 volts is applied the depletion layer extends 2× down into the layer. A problem exists at the edges of the trench (for example 45 degrees away from the long axis of trench depth). As the applied voltage increases, the depletion layer generally, tends to not increase much at the edges, as indicated by arrow “A” in FIG. 4. Without wishing to be bound by any one theory for operation of embodiments, it is believed that this pinching of the depletion layer occurs at the edges and thereby limits high voltage performance. The structural and chemical features discovered and claimed herein alleviate this pinch off problem and provides superior high voltage performance.

In a most desirable embodiment depletion layers that form at the bottom of the trenches expand uniformly. In an embodiment the definition of “expand uniformly” means that the depletion layer depth continues to expand (deepen) with increasing voltage to the same extent with increasing voltage (with plus/minus 50% deviation, and more preferably plus/minus 25% deviation).

In an embodiment a MOSFET made with the structural and chemical considerations outlined herein can withstand at least 100, 150, 200, 240 or even more volts between source and drain. Because of this structure, MOSFETs can be made having a higher voltage performance and in embodiments have high voltage capability to replace IGBTs in high voltage applications.

### An Embodiment

A desirable embodiment comprises a semiconductor substrate surface 500 with epitaxial grown material on surface 500 and having at least in part, a first type of dopant, as seen in FIG. 2. Trenches 510 having widths 225 are formed at defined intervals 230 generally perpendicular (preferably within 30 degrees from perpendicular, more preferably within 5 degrees from perpendicular) in epitaxial layer 530. Source electrodes 540 and gate electrodes 550 are inside trenches 510. Base regions are in a peripheral area 520 and outside trenches 510.

In a preferred embodiment, peripheral trenches are not present. In a preferred embodiment, instead, such complicated additional structures are avoided for achieving high voltage performance by a structural and optionally a chemical feature. Desirably, defined trench widths 225 and intervals 230 are adjusted to a ratio that was unexpectedly found to provide more even displacement zones during use. Preferably this ratio is between 1.0 and 2.5, particularly for the use of silicon based semiconductors. Other semiconductor materials can be used within this ratio and even other ratios, based on this disclosure, and are intended.

An embodiment provides a novel trench design having two gates formed on each side of a source, all in the trench. The trench extends downward from the surface of the chip. There are a plurality of essentially parallel trenches, with three trenches shown in an embodiment for illustrative purposes. Current flows primarily in a vertical direction between the source region on the top surface of the chip and a drain region on the opposing bottom surface of the chip.

In an embodiment the trench sides are lined with a dielectric layer, an insulator layer or no layer and the bottom of the trench is lined similarly. In an embodiment the width w1 of first and second gates 550 is preferably 0.001-10 microns. In an embodiment the width w1 is between 0.002 and 0.22 microns. In an embodiment the length is 0.5-100 microns. In another embodiment the length is between 1.0 and 10 microns. Desirably a channel is formed in a body region adjacent a wall of the trench. The two gates are biased positively in an enhancement-mode N-channel device, and are biased negatively in an enhancement-mode P-channel device. When the gates are properly biased the channel becomes inverted and allows current to flow between the source and the drain.

### Overall Structure: Improved Depletion Regions

FIG. 3 shows representative depletion regions within the semiconductor substrate under trenches formed according to embodiments. Trenches 310 are formed in substrate 320. Depletion region border 330 shows the edge of the depletion layer of the MOSFET device at 50 volts. Depletion region border 340 shows the edge of the depletion layer of the MOSFET device at 100 volts. Depletion region border 350 shows the edge of the depletion layer of the MOSFET device at 150 volts. As seen in this figure, as applied voltage increases there is a fairly linear uniform (plus/minus 25 percent, preferably within plus/minus 10 percent) expansion in the depletion layer. Note that the edges of the trench bottoms cause some change in the pattern, but do not create a non-homogeneous response to increased voltage across the depletion layer. Most importantly, the depletion region expansion at the edges of the trench bottoms in the area (shown for one trench) A are fairly uniform (i.e. within 50% preferably within 25% and more preferably within 10% of the linear values) compared to the rest of the depletion regions.

In contrast to the fairly uniform increase in depletion layer shown in FIG. 3, FIG. 4 shows the result with increasing voltage for a conventional structure. Trenches 410 are formed in substrate 420. The depletion region borders are shown with increasing voltage. Border 430 shows the extent of the depletion region for application of 50 volts. Border 440 shows depletion for application of 100 volts and border 450 shows the depletion region border for application of 150 volts. As seen in area A the depletion regions do not expand uniformly but become locally dense at the edges of the trench bottoms. This causes a lowering of breakdown voltage.

In an embodiment the non uniform depletion layer (shown as dense region A in FIG. 4) is alleviated by adjusting defined trench widths and the defined intervals between trenches are at a ratio of 1.0 to 2.5 respectively. In an embodiment the non uniform depletion layer (shown as dense region A in FIG. 4) is alleviated by adjusting base dopant concentration to between 5×10E16 to 5×10E17 per cubic centimeter. In another embodiment the non uniform depletion layer (shown as dense region A in FIG. 4) is alleviated by adjusting the epitaxial layer to a dopant concentration of between 1.2E16 to 1.8E16 N− per cubic centimeter. In a preferred embodiment the structural adjustments are combined with one or both chemical adjustments to achieve the more uniform expansion of depletion layer with increasing voltage.

### Lack of Peripheral Trench

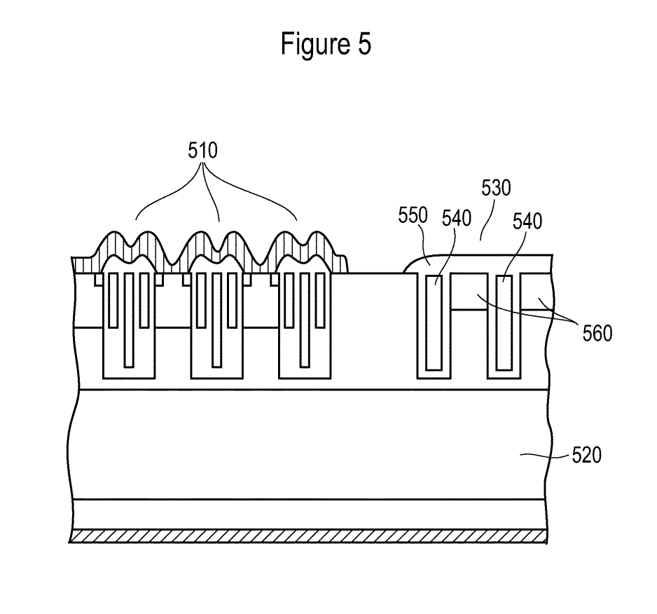

An embodiment provides higher current density structures by avoiding the need for peripheral trenches and using the substrate more efficiently. FIG. 5 shows active device trenches 510 in semiconductor 520 with peripheral dummy trenchs area 530 comprising dummy trench gates 540. Silicon oxide 550 typically caps such structures. Preferably such structures are not used and more space is available for active MOSFET trenches. In an embodiment only one peripheral dummy trench is used instead of multiple dummy trenches. In a more desirable embodiment no peripheral dummy trenches are used.

### Top and End Views

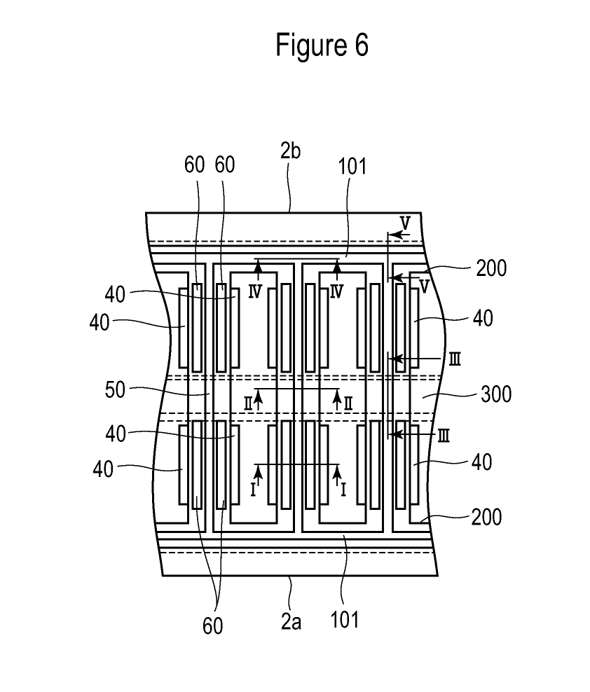

FIG. 6 shows a top view of an embodiment. Top portion 2b and bottom portion 2a are edges of the substrate. Connected trenches 101 are seen in this top view. First upper electrode 300 and second upper electrode 200 are shown. IGate electrodes 60 are parallel to trench source electrodes 50, which are connected to connector 101. Source regions 40 are positioned at the top and to the side of the trenches. As seen in this figure trench source electrodes 50 are connect adjacent cells as seen vertically in this figure.

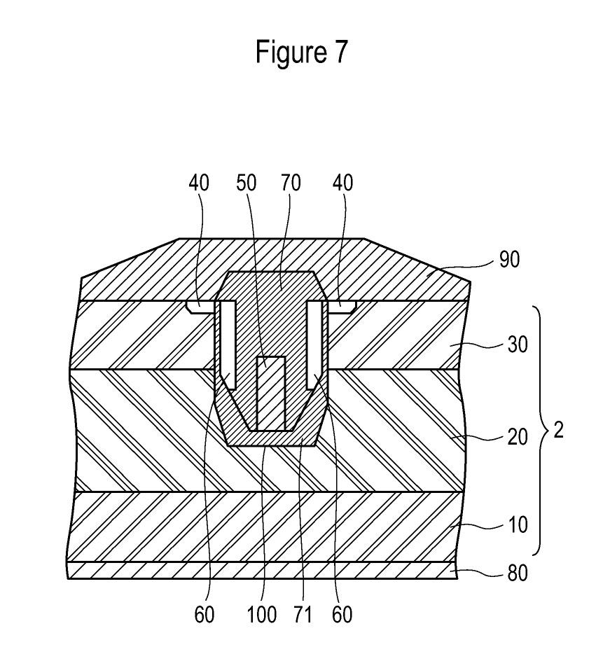

FIG. 7 shows an end view of a trench structure according to an embodiment. Element 80 on the bottom is a drain electrode. Element 10 is an N+ layer. Element 20 is an N− layer. Element 30 is a P− layer. Element 90 is an insulating layer.

The trench bottom 100 is flat but preferably the lower portion of the side wall is beveled inwards as shown here on the left and right sides of the bottom edge in this end view. Gate electrodes 60 preferably have an upper surface in the plane of the upper surface of the P− layer as shown. Gate electrodes 60 preferably extend below the lower edge surface of the P-layer as shown. In an embodiment the gate electrodes have an outer surface away from the trench center that is oblique to the vertical direction.

In the example shown the electrode outer edge angles away from the outer wall edge starting at a point just below the lower surface of the P− layer. This angle (shown as the entry point surface of indicator line from “60” in FIG. 7) is between 15 and 60 degrees and more preferably between 25 and 45 degrees as shown in FIG. 7. Trench source electrode 50 preferably extends from above the lower surface of the P− layer to the trench bottom. In an embodiment an insulator such as silicon dioxide covers the trench bottom and approximately the lower half of the side wall more thickly than the insulation between gate electrode 60 and adjacent source region 40 and P− region layer 30. In an embodiment the insulation increases gradually from a point just below the lower surface of P-layer 30 to the bottom as shown. In an embodiment the insulation thickness is greatest on the edges of the trench bottom 71 as shown.

### Capacitance in a Power MOSFET

An important performance criterion is the capacitance between the gate and drain (Cgd), which determines the MOSFET's ability to switch current quickly and operate at high frequencies. In a standard trench-gated MOSFET, the gate-to-drain capacitance is measured across the gate oxide layer at the bottom of the trench, which separates the gate electrode from the drain. In the trench-gated MOSFET of embodiments described here this gate to drain capacitance is minimized.

The rate at which the power MOSFET structure can be switched ON and OFF is determined by the rate at which the input capacitance can be charged and discharged. The capacitance between the drain and gate electrodes plays an important role in computing the drain current and the voltage changes during switching. The thickness of the gate oxide and the trench width are two factors that are known to have a primary effect on the input capacitance of a MOSFET.

It is also known that the input capacitance for a power MOSFET structure with the source electrode in the trench is larger than that for the structure with the gate electrode in the entire trench region. The input capacitance is due to the gate electrode overlap with the P-base and N+ source regions on the trench sidewall.

When the source electrode is embedded in a trench, another capacitance to deal with is that due to overlap of the source metal electrode and the overlap of the gate electrode with the source electrode embedded in the trench. A specific gate (or input) capacitance for a power MOSFET structure with the source embedded in the trench can be calculated using known equations. The total capacitance is a function of the thickness of the gate oxide and inter-electrode oxide, and the oxide between the gate and source electrodes within the trench. The gate-drain capacitance with the gate electrode in the entire trench region is determined by summing the capacitance contributed along the trench sidewalls and the capacitance at the trench bottom.

Embodiments described herein are exemplary only. Other embodiments will be readily apprehended by a skilled artisan reader having a degree in solid state physics and two years experience working in development of MOSFET devices. Space and time limitations preclude further description herein. Details such as numeric dimensions, angles, positioning, relative and actual dimensions, materials and methods relating to physical and structural construction of MOSFET devices described in the cited references are specifically incorporated by reference herein and are intended as possible claimed features.

1. A semiconductor power device disposed in a semiconductor substrate, comprising:
trenches having defined widths formed at defined intervals perpendicular to and across a top portion of the semiconductor substrate extending laterally across the substrate and extending into an epitaxial layer;
base regions located outside the trenches;
trench source electrodes inside the trenches; and
gate electrodes inside the trenches positioned between the trench source electrodes and the base regions, wherein
a ratio of the intervals between trenches and the widths of the trenches is from 1.0 to 2.5.

2. The semiconductor power device of claim 1, wherein a dopant concentration of the base regions is between 5×10E16 to 5×10E17 per cubic centimeter.

3. The semiconductor power device of claim 1, wherein the epitaxial layer has an N− dopant concentration of between 1.2E16 to 1.8E16 N− per cubic centimeter.

4. The semiconductor power device of claim 2, wherein the epitaxial layer has an N− dopant concentration of between 1.2E16 to 1.8E16 N− per cubic centimeter.

5. The semiconductor power device of claim 1, lacking a peripheral trench structure.

6. The semiconductor power device of claim 1, wherein the trench source electrodes are centered in the trenches, and extend mostly to the bottom of the trenches.

7. The semiconductor power device of claim 6, wherein the gate electrodes are between the trench source electrodes and the trench walls, and extend only partially into the trenches adjacent to the base regions.

8. The semiconductor power device of claim 7, wherein the base regions are at the top of the epitaxial layer and extend down as far as the gate electrodes

9. The semiconductor power device of claim 1, wherein the trench widths are approximately 1.5 microns, wherein approximately comprises+/−20%.

10. The semiconductor power device of claim 9, wherein the spacing between trenches is approximately 1.7 microns.

11. The semiconductor power device of claim 1, having depletion regions along the trenches that expand uniformly with applied voltage.

12-20. (canceled)
